(19) United States
(12) Patent Application Publication
(10) Pub. No.: US 2012/0098791 A1
(43) Pub. Date: Apr. 26, 2012

(54) TOUCH PANELS, METHOD FOR FABRICATING TOUCH PANELS, DISPLAY DEVICES, AND METHOD FOR FABRICATING DISPLAY DEVICES

(75) Inventors: Hiroshi Hamada, Osaka-shi (JP); Minoru Mayumi, Osaka-shi (JP)

(73) Assignee: SHARP KABUSHIKI KAISHA, Osaka-shi (JP)

(21) Appl. No.: 13/381,339

(22) PCT Filed: Mar. 3, 2010
(86) PCT No.: PCT/JP2010/001468

§ 371 Date: Dec. 28, 2011

(30) Foreign Application Priority Data
Jun. 30, 2009 (JP) 2009-155195

(51) Int. Cl. G06F 3/044; H05K 3/08; H05K 3/00

(52) U.S. Cl. 345/174; 29/846; 29/847

(57) ABSTRACT

A touch panel includes a touch region for detecting a location of a touch by an object, and a plurality of touch location detection electrodes arranged in the touch region. The touch panel is configured to detect the location of the touch based on a capacitance formed between the touch location detection electrodes and the object. An optical characteristic of a gap between the touch location detection electrodes adjacent to each other is substantially equal to an optical characteristic of the touch location detection electrodes.

### REFERENCE TO RELATED APPLICATIONS

This application is the national stage under 35 USC 371 of International Application No. PCT/JP2010/001468, filed Mar. 3, 2010, which claims the priority of Japanese Patent Application No. 2009-155195, filed Jun. 30, 2009, the entire contents of which are incorporated herein by reference.

### TECHNICAL FIELD

The present invention relates to capacitive touch panels, a method for fabricating the capacitive touch panels, display devices, and a method for fabricating the display devices.

### BACKGROUND ART

Touch panels for detecting a location of contact have widely been used (see, e.g., Patent Document 1 etc.). The touch panels are often placed on, for example, display devices such as liquid crystal display panels.

The touch panels are classified into resistive film touch panels, capacitive touch panels, infrared touch panels, ultrasonic touch panels, electromagnetic induction touch panels, etc., based on their working principles. Among them, the capacitive touch panels have relatively little effect on optical characteristics of the display devices, and have been known as suitable touch panels for the display devices.

The capacitive touch panels include surface capacitive touch panels, and projected capacitive touch panels. In general, the former touch panel includes a transparent electrode which is provided on the entire surface of a touch region to detect a location of a touch, a linearizing electrode including a plurality of segments positioned along a perimeter of the transparent electrode to linearize electric field distribution in the touch region, and a current detection circuit which applies a constant alternating voltage to terminals provided at four corners of the linearizing electrode, and detects a current flowing through the terminals. The transparent electrode is covered with a protective insulating film. When the insulating film in the touch region is touched, the transparent electrode is grounded through a capacitance formed between the transparent electrode and a human body at the location of the touch. Based on the location of the touch, impedance between the terminals and the grounded part varies, and the current detection circuit detects the variation. Thus, the location of the touch is detected based on the variation in impedance (Patent Document 1).

The projected capacitive touch panel includes, in general, X electrodes and Y electrodes arranged in a matrix pattern, and is configured to detect a change in earth capacitance of each electrode by the touch, or a change in mutual capacitance at a point of intersection of the X and Y electrodes by a capacitive detection circuit, thereby detecting the location of the touch (Patent Document 2).

In this technology, two different transparent substrates on which the X electrodes and the Y electrodes are formed, respectively, may be stacked, or the X electrodes and the Y electrodes may be formed on different surfaces of a single transparent substrate to electrically isolate the intersections of the X and Y electrodes.

Patent Documents 3 and 4 disclose a configuration in which the Y electrodes are not continuously formed, but are discontinuously formed in gaps between the X electrodes, and the discontinuous Y electrodes are electrically connected by connectors extending across the X electrodes.

Patent Document 5 discloses a method for obtaining X and Y coordinates of the location of the touch based on distribution of a capacitance formed between alternately arranged triangular (wedge-shaped) electrodes and an object to be detected (a finger etc.). The electrodes arranged in this manner are advantageous because they can be formed in a single process.

Although the conventional touch panels are substantially flat touch panels, there are potential demands for curved (non-flat) touch panels as an appealing and attractive user interface. However, it is impossible or practically difficult to provide the resistive film touch panels, infrared touch panels, ultrasonic touch panels, and electromagnetic induction touch panels with a non-flat surface. On the other hand, a practical non-flat capacitive touch panel can be fabricated as proposed by the inventors of the present invention in Patent Document 6.

### CITATION LIST

### Patent Documents

[Patent Document 1] Japanese Translation of PCT International Application No. 2005-530274

[Patent Document 2] Japanese Translation of PCT International Application No. 2003-511799

[Patent Document 3] Japanese Utility Model Registration No. 3144241

[Patent Document 4] Japanese Utility Model Registration No. 3144563

[Patent Document 5] United States Patent No. 4999462

[Patent Document 6] International Patent Publication No. WO2007/099733

### SUMMARY OF THE INVENTION

The inventors of the present invention have studied a so-called multi-touch panel which can detect various types of touch inputs on the touch region for detecting the location of the touch.

The surface capacitive touch panel merely detects the location of the touch of a single object in principle. To achieve the multi-touch function, electrodes for detecting the location of the touch arranged in a touch region of a projected capacitive touch panel need to be arranged in a plurality of electrode patterns. According to a conventional method for forming the touch location detection electrodes, an indium tin oxide (ITO) film is formed by sputtering, and is photo-etched into a desired electrode pattern. However, this method requires a vacuum device and a photo-etching device which are expensive.

For this reason, an organic transparent conductive film (a transparent conductive film) has been developed as an alternative of the ITO film. When the organic transparent conductive film is used, the touch location detection electrodes can be formed at lower cost by printing than by photolithography. However, unlike the photolithography, a gap between the adjacent electrodes cannot be 100 μm or smaller by screen printing. Further, when the printing is employed, the gap between the electrodes, and the electrodes have different light transmittances. Thus, the gap between the electrodes is quite prominent, thereby reducing quality of display.

Further, the organic transparent conductive film is slightly colored, and makes the appearance unattractive. When the organic transparent conductive film is thinned to make the color light, a resistance of the organic transparent conductive film increases, and the organic transparent conductive film cannot be used as the touch location detection electrodes.

An ITO transfer film has been developed as a transparent conductive film (a conductive film). The ITO transfer film includes a stack of a transparent conductive layer containing multiple ITO particles, and an adhesive layer. The ITO transfer film can be adhered to a substrate in the atmosphere, and can provide the touch location detection electrodes without using the expensive vacuum device.

When the ITO transfer film is used to form the plurality of touch location detection electrodes, the ITO transfer film adhered to the substrate can be processed by a laser using a laser patterning device (a laser marker).

In this case, however, part from which the ITO transfer film is removed by the laser application has a refractive index and a transmittance different from those of the ITO electrodes. Thus, the shape of the touch location detection electrodes is visible to users, which reduces the quality of display.

In view of the foregoing, the present invention has been achieved. The present invention is concerned with making the shape of the touch location detection electrodes less visible to the users.

In view of the above concern, a touch panel of the present invention includes: a touch region for detecting a location of a touch by an object; and a plurality of touch location detection electrodes arranged in the touch region, the touch panel being configured to detect the location of the touch based on a capacitance formed between the touch location detection electrodes and the object, wherein an optical characteristic of the touch region in a gap between the touch location detection electrodes adjacent to each other is substantially equal to an optical characteristic of the touch location detection electrodes.

Each of the touch location detection electrodes may be formed with a conductive film including a transparent conductive layer, and an adhesive layer stacked on the transparent conductive layer, an insulating translucent material may be provided in the gap between the touch location detection electrodes adjacent to each other, and a refractive index of the translucent material may be equal to a refractive index of the adhesive layer or a refractive index of the transparent conductive layer, or may be a median between the refractive index of the adhesive layer and the refractive index of the transparent conductive layer.

The gap may be formed by applying a laser to the conductive film.

The transparent conductive layer may be formed with a layer containing multiple transparent conductive particles.

The touch panel of the present invention includes: a touch region for detecting a location of a touch by an object; and a plurality of touch location detection electrodes arranged in the touch region, the touch panel being configured to detect the location of the touch based on a capacitance formed between the touch location detection electrodes and the object, wherein the touch location detection electrodes are formed with a transparent conductive film, an insulating translucent material is provided in a gap between the touch location detection electrodes adjacent to each other, and light transmittance and color tone of the translucent material are the same as light transmittance and color tone of the transparent conductive film.

The transparent conductive film may be made of a transparent conductive material which is water-soluble before curing, and the translucent material may be a water-repellent coloring material.

A display device of the present invention includes the touch panel formed directly on a surface of a substrate constituting a display element.

A method for fabricating a display device of the present invention is a method for fabricating the above-described display device. The method includes: bonding a first substrate on which a liquid crystal material is fed by dropping to a second substrate to form a large base substrate as an assembly of multiple ones of the display element; forming the touch panel directly on a surface of the first or second substrate of the base substrate; and dividing the base substrate on which the touch panel is formed by the display elements to fabricate a plurality of liquid crystal display devices.

A method for fabricating a touch panel of the present invention is a method for fabricating a touch panel which includes a touch region for detecting a location of a touch by an object, and a plurality of touch location detection electrodes arranged in the touch region, and is configured to detect the location of the touch based on a capacitance formed between the touch location detection electrodes and the object. The method includes: bonding a conductive film including a transparent conductive layer and an adhesive layer stacked on the transparent conductive layer to a substrate with the adhesive layer facing the substrate; forming the plurality of touch location detection electrodes by applying a laser to the conductive film bonded to the substrate; and providing an insulating translucent material in a gap between the touch location detection electrodes adjacent to each other, wherein a refractive index of the translucent material is equal to a refractive index of the adhesive layer or a refractive index of the transparent conductive layer, or is a median between the refractive index of the adhesive layer and the refractive index of the transparent conductive layer.

The transparent conductive layer may be formed with a layer containing multiple transparent conductive particles.

A method for fabricating a touch panel of the present invention is a method for fabricating a touch panel which includes a touch region for detecting a location of a touch by an object, and a plurality of touch location detection electrodes arranged in the touch region, and is configured to detect the location of the touch based on a capacitance formed between the touch location detection electrodes and the object. The method includes: forming on a substrate the plurality of touch location detection electrodes formed with a transparent conductive film, and an insulating translucent material provided in a gap between the touch location detection electrodes adjacent to each other, wherein light transmittance and color tone of the translucent material are the same as light transmittance and color tone of the transparent conductive film.

The transparent material made of a water-repellent coloring material may be formed on the substrate, and then a water-soluble transparent conductive material may be applied and cured to form the transparent conductive film.

The substrate on which the plurality of the touch location detection electrodes and the translucent material are formed is divided to fabricate multiple ones of the touch panel.

Advantages of the present invention will be described below.

When the object touches the touch region of the touch panel, a capacitance is formed between the object and the touch location detection electrodes (hereinafter abbreviated as the electrodes), and the location of the touch is detected based on a change in capacitance.

When the electrodes are formed with the conductive film including the transparent conductive layer and the adhesive layer stacked on the transparent conductive layer, the gaps between the electrodes are formed by, e.g., applying a laser to the conductive film adhered to a substrate. This allows easy formation of the plurality of electrodes.

The transparent conductive layer is formed with, for example, the layer containing multiple transparent conductive particles. This can provide a suitable conductive film.

In this case, the insulating translucent material is provided in the gap, and the refractive index of the translucent material is set equal to the refractive index of the adhesive layer or the refractive index of the transparent conductive layer, or is set to a median between the refractive index of the adhesive layer and the refractive index of the transparent conductive layer. Thus, a difference between the refractive index of the gap and the refractive index of the electrodes surrounding the gap can be reduced. This can make the shape of the electrodes less visible to users.

When the electrodes are made of the transparent conductive film, the translucent material having the same light transmittance and color tone as the transparent conductive film is provided in the gap between the electrodes adjacent to each other. This can make the translucent material provided in the gap and the electrodes surrounding the gap less distinguishable, and can suitably make the shape of the electrodes less visible.

For example, when the translucent material made of the water-repellent coloring material is formed on the substrate, and then the water-soluble transparent conductive material is applied, the transparent conductive material is repelled by the translucent material. Thus, it is no longer necessary to form the plurality of electrodes by patterning, and the plurality of electrodes with the translucent material provided in the gap therebetween can easily be formed.

For example, when the electrodes and the translucent material are directly formed on the substrate constituting the display element such as a liquid crystal display element, a display device provided with the touch panel in which the shape of the electrodes is less visible can be formed with a reduced thickness.

The first substrate on which the liquid crystal material is fed by dropping is bonded the second substrate to form the large base substrate as an assembly of multiple ones of the display element, and the touch panel is directly formed on the surface of the first or second substrate of the base substrate. Then, the base substrate on which the touch panel is formed is divided by the display elements. Thus, a plurality of liquid crystal display devices can be fabricated.

According to the present invention, when the touch location detection electrodes are formed with the conductive film including the transparent conductive layer, and the adhesive layer stacked on the transparent conductive layer, the insulating translucent material is provided in the gap between the touch location detection electrodes adjacent to each other, and the refractive index of the translucent material is set equal to the refractive index of the adhesive layer or the refractive index of the transparent conductive layer constituting the conductive film, or is set to a median between the refractive index of the adhesive layer and the refractive index of the transparent conductive layer. This can reduce a difference between the refractive index of the gap and the refractive index of the electrodes surrounding the gap. Thus, the shape of the electrodes can be less visible to the users.

When the touch location detection electrodes are formed with the transparent conductive film, the translucent material having the same light transmittance and color tone as the transparent conductive film is provided in the gap between the touch location detection electrodes adjacent to each other. This can make the translucent material provided in the gap and the electrodes surrounding the gap less distinguishable, and can make the shape of the touch location detection electrodes less visible.

### BRIEF DESCRIPTION OF THE DRAWINGS

FIG. 1 is a plan view illustrating a touch panel according to a first embodiment.

FIG. 2 is a cross-sectional view illustrating a liquid crystal display device 1 on which a touch panel of a third embodiment is formed.

FIG. 3 is a cross-sectional view illustrating an enlargement of a touch location detection electrode adhered to a substrate.

FIG. 4 is a plan view illustrating a general structure of a base substrate.

FIG. 5 is a cross-sectional view illustrating the base substrate.

FIG. 6 is a flowchart illustrating steps of fabricating the touch panel of the first embodiment.

FIG. 7 is a flowchart illustrating steps of fabricating a touch panel of a second embodiment.

FIG. 8 is a plan view schematically illustrating the touch panel of the third embodiment.

FIG. 9 is a plan view illustrating a partial enlargement of FIG. 8.

FIG. 10 is a cross-sectional view schematically illustrating the touch panel of the third embodiment.

FIG. 11 is a plan view schematically illustrating a touch panel of a fifth embodiment.

### DETAILED DESCRIPTION OF THE INVENTION

Embodiments of the present invention will be described in detail with reference to the drawings. The present invention is not limited to the following embodiments.

### First Embodiment of the Invention

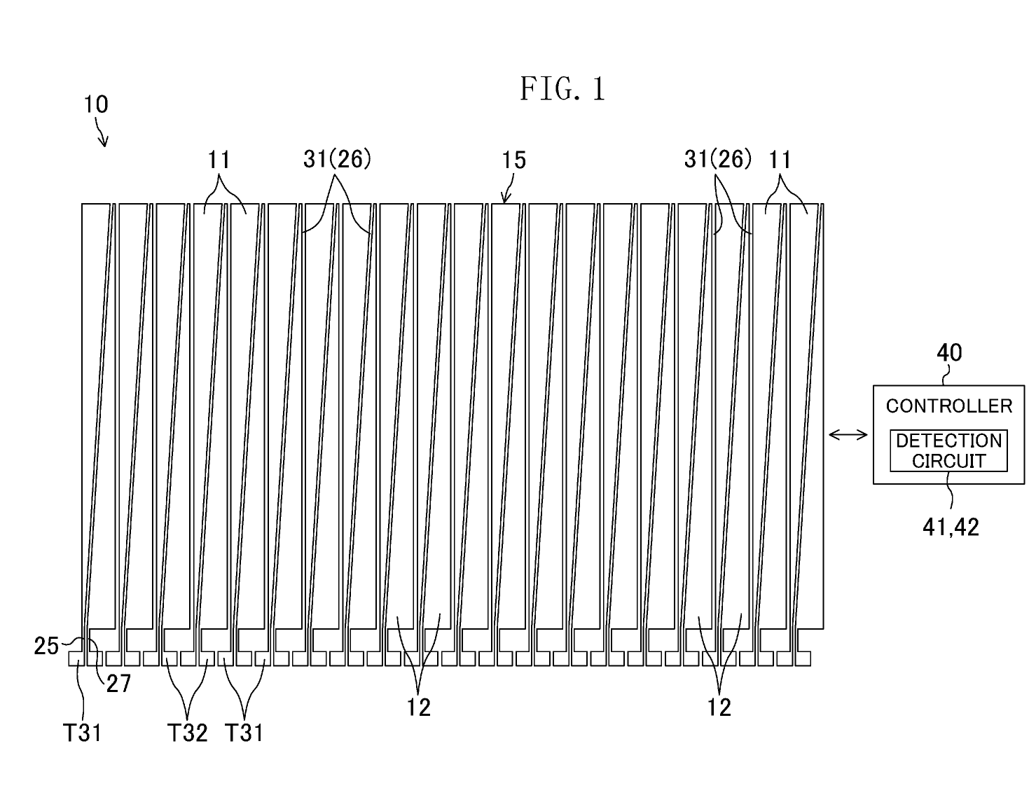

FIGS. 1-6 show a first embodiment of the present invention.

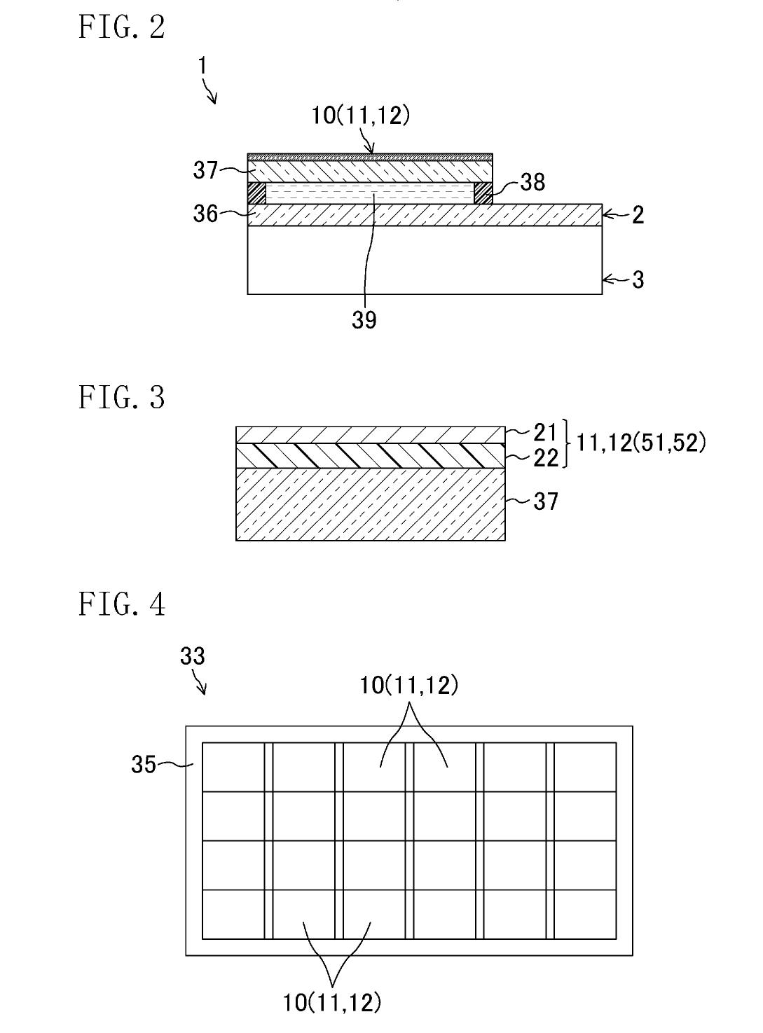

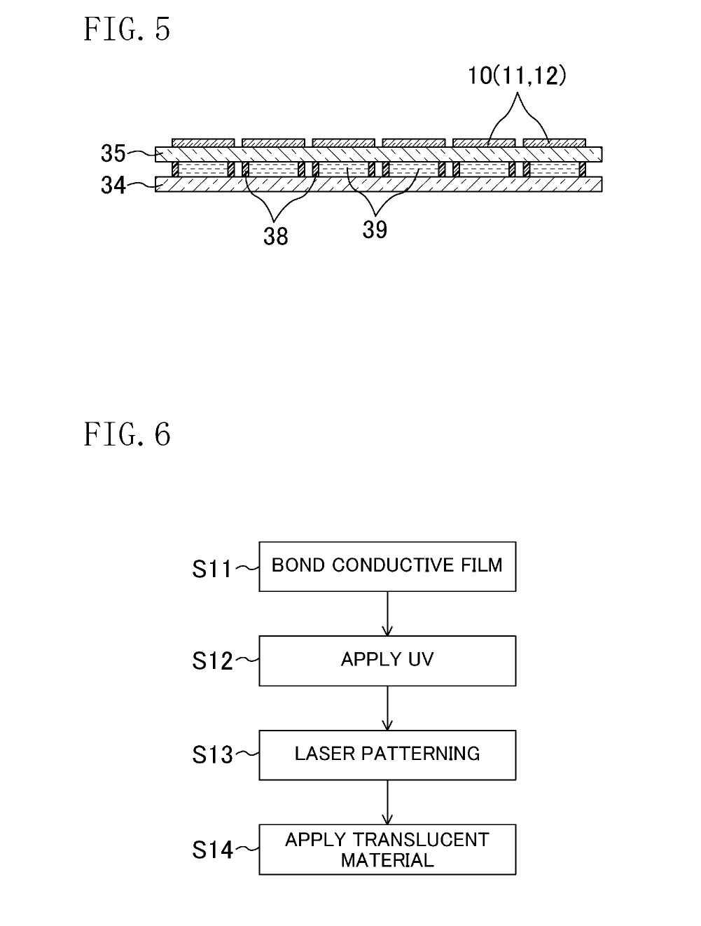

FIG. 1 is a plan view illustrating a touch panel 10 of the first embodiment. FIG. 2 is a cross-sectional view illustrating a liquid crystal display device 1 on which a touch panel 10 of a third embodiment is formed. FIG. 3 is a cross-sectional view illustrating an enlargement of a touch location detection electrode 11, 12 bonded to a substrate 37. FIG. 4 is a plan view illustrating a base substrate 33. FIG. 5 is a cross-sectional view illustrating the base substrate 33.

In the present embodiment, a liquid crystal display device 1 including a liquid crystal display panel 2 as a display panel will be described as an example of display devices.

### —Structure of Liquid Crystal Display Device—

As shown in FIG. 2, the liquid crystal display device 1 includes a liquid crystal display panel 2 as a display element, a back light unit 3 which is a light source arranged on a back surface of the liquid crystal display panel, and a touch panel 10 arranged opposite the back light unit 3 relative to the liquid crystal display panel 2. Specifically, the touch panel 10 is arranged to face the liquid crystal display panel 2.

The liquid crystal display panel 2 includes a TFT substrate 36 on which a plurality of pixel electrodes (not shown), and thin film transistors (TFTs: not shown) as switching elements are arranged in a matrix pattern, a counter substrate 37 which is arranged to face the TFT substrate 36, and on which color filters, common electrodes, etc., which are not shown, are formed, and a liquid crystal layer 39 provided between the counter substrate 37 and the TFT substrate 36. The liquid crystal layer 39 is sealed between the counter substrate 37 and the TFT substrate 36 with a frame-shaped sealing member 38 surrounding the liquid crystal layer.

In the present invention, the touch panel 10 is directly formed on an outer surface of the counter substrate 37 constituting the liquid crystal display panel 2.

### —Structure of Electrodes of Touch Panel—

The touch panel 10 of the present embodiment is a capacitive touch panel, and includes a touch region 15 for detecting a location of a touch by an object (a finger of a user etc.), a plurality of touch location detection electrodes 11, 12 which are arranged in the touch region 15, and a controller 40 as a detection circuit for detecting the location of the touch based on a change in capacitance formed between the touch location detection electrodes 11, 12 and the object.

The touch location detection electrodes 11, 12 include first electrodes 11 and second electrodes 12. The touch location detection electrodes 11, 12 of the present embodiment are formed with an ITO transfer film as a conductive film. FLECLEAR (a registered trademark of TDK Corporation) can suitably be used as the ITO transfer film.

As shown in FIG. 3, the conductive film 11, 12 includes a transparent conductive layer 21, and an adhesive layer 22 stacked on the transparent conductive layer 21. The transparent conductive layer 21 is formed with, for example, a layer containing multiple transparent conductive particles. The transparent conductive particles are, for example, fine ITO particles. The adhesive layer 22 is made of, for example, an ultraviolet curable adhesive.

Each of the first electrodes 11 and the second electrodes 12 is in the shape of a narrow right triangle as shown in FIG. 1. The first and second electrodes 11 and 12 are arranged with their hypotenuses parallel to each other in such a manner that a pair of the first and second electrodes 11 and 12 forms a narrow rectangle. Multiple pairs of the first and second electrodes 11 and 12 are arranged to form the touch region 15 which is rectangular as a whole. A gap 26 is formed between the electrodes 11, 12 adjacent to each other.

As shown in FIG. 1, wires 25 are drawn from the first electrodes 11 to a side of the touch region 15, and terminals T31 are formed at the ends of the wires. Likewise, wires 27 are drawn from the second electrodes 12 to the side of the touch region 15, and terminals T32 are formed at the ends of the wires. The terminals T31, T32 are alternately aligned. The terminals T31, T32 are connected to the controller 40 through a metal wire pattern, a silver paste print pattern, FPC, etc. (not shown) formed by a known technology.

The gaps 26 are formed by bonding the conductive film to the substrate 37 with the adhesive layer 22, and processing the conductive film with a laser beam. Specifically, the first and second electrodes 11 and 12 are formed by processing the conductive film bonded to the counter substrate 37 with the laser beam.

An insulating translucent material 31 is provided in the gap 26 between the touch location detection electrodes 11, 12 adjacent to each other. A refractive index of the translucent material 31 is equal to a refractive index of the adhesive layer 22 constituting the first and second electrodes 11 and 12 or a refractive index of the transparent conductive layer 21, or is a median between the refractive indices of the adhesive layer 22 and the transparent conductive layer 21. The translucent material 31 is, for example, an ultraviolet curable resin, or a thermosetting resin. This can make the pattern of the first and second electrodes 11 and 12 less visible.

The translucent material 31 preferably has the same light transmittance and color tone as the conductive film constituting the first and second electrodes 11 and 12 (i.e., the entire layer including the transparent conductive layer 21 and the adhesive layer 22). In some cases, the conductive film is transparent and is slightly colored. In such cases, the translucent material 31 may preferably be slightly colored like the conductive film. This can make the pattern of the first and second electrodes 11 and 12 much less visible.

### —Structure of Controller—

The controller 40 includes a capacitance detection circuit 41 for detecting a change (increase) in capacitance formed between the object and the first and second electrodes 11 and 12 when the object touches the touch region 15, or an impedance detection circuit 42 for detecting a change in impedance formed in each of the first and second electrodes 11 and 12 when the object touches the touch region 15. The second electrodes 12 are connected to the capacitance detection circuit 41 or the impedance detection circuit 42 independently or in groups. Tip ends 17 of the first electrodes 11 are connected to the capacitance detection circuit 41 or the impedance detection circuit 42.

The controller 40 is configured to compare signals from the terminals T31 of the tip ends 17 detected by the capacitance detection circuit 41 or the impedance detection circuit 42 to detect a location of a touch by the object on the touch region 15, and movement of the location of the touch.

### —Method for Detecting Location of Touch—

A method for detecting the location of the touch by the controller 40 will be described below.

When a user's finger touches the touch region 15, the controller 40 detects whether a capacitance is formed in the touch region 15 or not through the terminals T31, T32, thereby detecting the touch. Thus, a predetermined region displayed on the liquid crystal display panel 2 can be selected by the touch.

When the user moves the finger on the surface of the touch region 15, for example, pages can be scrolled based on the movement of the location of the touch.

For example, when the user's finger touches the second electrode 12 in FIG. 1, a capacitance corresponding to a touched area is output to the controller 40. Then, as the user's finger moves to the right or left in FIG. 1, the touched area of the second electrode 12 is decreased, and a touched area of the first electrode 11 is increased. The controller 40 detects the movement of the location of the touch based on the increase and decrease of the touched area of each electrode, and generates a signal for image formation corresponding to the detected movement. A series of the detection is performed in the same manner when the location of the touch moves again from the first electrode 11 to the second electrode 12.

### —Fabrication Method—

A method for fabricating the touch panel 10 and the liquid crystal display device 1 will be described below.

The liquid crystal display device 1 is fabricated by stacking a backlight unit 3 on a back surface of the liquid crystal display panel 2. The touch panel 10 is fabricated by forming the first and second electrodes 11 and 12, etc., on the counter substrate 37 of the liquid crystal display panel 2.

In the first embodiment, as shown in FIGS. 4 and 5, the base substrate 33 on which a plurality of touch panels 10 are directly formed is divided into pieces to form a plurality of liquid crystal display panels 2.

Specifically, in a step of forming the base substrate, a first substrate 34 on which a liquid crystal material is fed by dropping is bonded to a second substrate 35 to form a large base substrate 33 as an assembly of a plurality of liquid crystal display panels 2.

For example, the first substrate 34 is an assembly of a plurality of TFT substrates 36 arranged in a matrix pattern. Likewise, the second substrate 35 is an assembly of a plurality of counter substrates 37 arranged in a matrix pattern.

A plurality of frame-shaped sealing members 38 are arranged in a matrix pattern on one of the surfaces of the first substrate 34. A liquid crystal material is fed by dropping in the inside of each of the sealing members 38. The second substrate 35 is then bonded to the first substrate 34 to sandwich the liquid crystal material and the sealing members 38 therebetween. Thus, the base substrate 33 is formed.

Then, in a step of forming the touch panel, the touch panels 10 are formed directly on a surface of the second substrate 35 of the base substrate 33. When the first substrate 34 is the assembly of the counter substrates 37, the touch panels 10 may be formed on the first substrate 34.

In a dividing step, the base substrate 33 on which the touch panels 10 are formed is divided by the liquid crystal display panels 2. Thus, a plurality of liquid crystal display devices 1 are fabricated.

The step of forming the touch panel will be described in detail below. In the step of forming the touch panel, a pattern of the first and second electrodes 11 and 12 shown in FIG. 1 is formed on an outer surface of the second substrate 35.

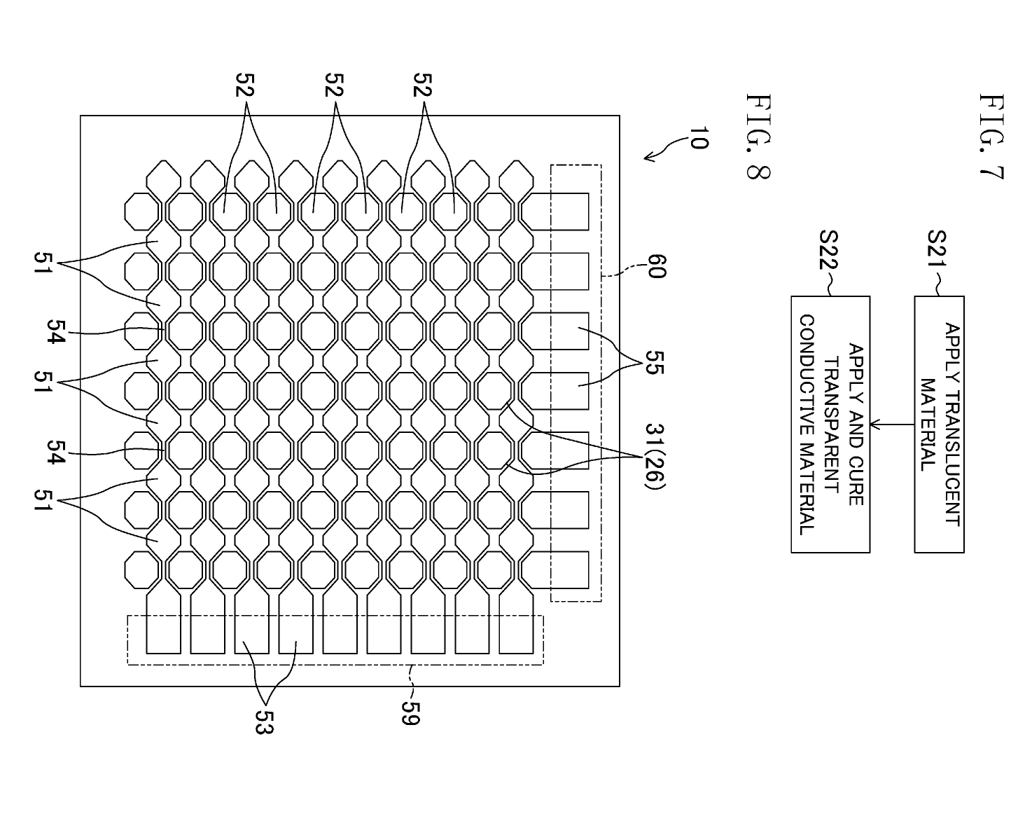

Specifically, in a first step shown as S11 in FIG. 6, FLECLEAR (a registered trademark of TDK Corporation), which is an ITO transfer film as the conductive film, is transferred to the outer surface of the second substrate 35 with the adhesive layer 22 facing the outer surface.

Then, the flow proceeds to a second step S12 to apply ultraviolet light to the adhesive layer 22 of the conductive film to cure the adhesive layer 22. Thus, the conductive film is adhered and fixed to the second substrate 35.

Then, the flow proceeds to a third step S13 to apply a laser to the conductive film adhered to the substrate 35, thereby forming a plurality of touch location detection electrodes 11, 12. In this step, the first and second electrodes 11 and 12 are formed, and wires 25, 27 drawn from the electrodes, and terminals T31, T32 are patterned using a laser patterning device, such as a laser marker etc. The application of the laser forms a gap 26 between the first and second electrodes 11 and 12 adjacent to each other.

The laser patterning device preferably emits a laser having a wavelength which can pass through the substrate 35 without damaging the color filters, the counter electrodes, the liquid crystal material, the TFTs, etc. in the liquid crystal panel, i.e., an ultraviolet laser (e.g., a laser having a wavelength three or four times greater than a YAG laser), or an infrared laser. A long wavelength CO₂ laser is particularly preferable. This can prevent damage to the inside of the liquid crystal display panel 2.

The flow proceeds to a fourth step S14 to provide an insulating translucent material 31 in the gap 26 between the first and second electrodes 11 and 12 adjacent to each other. The translucent material 31 is, for example, an ultraviolet curable resin, or a thermosetting resin. The translucent material 31 may preferably be colored to have the same light transmittance and color tone as the first and second electrodes 11 and 12. The translucent material 31 applied to fill the gap 26 is cured by applying ultraviolet light, or by heating.

As described above, a refractive index of the cured translucent material 31 is equal to a refractive index of the adhesive layer 22 or a refractive index the transparent conductive layer 21 constituting the first and second electrodes 11 and 12, or is a median between the refractive indices of the adhesive layer 22 and the transparent conductive layer 21.

Then, a controller 40 is formed on the second substrate 35 or the first substrate 34, and the terminals T31, T32 are connected to the controller 40. Thus, the touch panel 10 is fabricated.

### Advantages of First Embodiment

According to the first embodiment, the first and second electrodes 11 and 12, which are the touch location detection electrodes 11, 12, are formed with the conductive film including the transparent conductive layer 21, and the adhesive layer 22 stacked on the transparent conductive layer 21. Thus, the first and second electrodes 11 and 12 can easily be formed by processing the conductive film adhered to the substrate 35 by a laser.

Further, the refractive index of the translucent material 31 provided in the gap 26 between the touch location detection electrodes 11, 12 adjacent to each other is set equal to the refractive index of the adhesive layer 22 or the refractive index of the transparent conductive layer 21 constituting the conductive film, or is set to a median between the refractive indices of the adhesive layer 22 and the transparent conductive layer 21. This can reduce a difference between the refractive index of the gap 26 and the refractive index of the electrodes 11, 12 surrounding the gap. Thus, the pattern of the touch location detection electrodes 11, 12 can be less visible to the users, thereby improving quality of display on the liquid crystal display device 1.

The translucent material 31 is colored like the first and second electrodes 11 and 12. Thus, the translucent material 31 has the same light transmittance and color tone as the first and second electrodes 11 and 12. This can make the translucent material 31 and the electrodes 11, 12 surrounding the translucent material less distinguishable. Specifically, this can suitably make the shape of the electrodes 11, 12 less visible, thereby suitably improving the quality of display on the liquid crystal display device 1.

### Second Embodiment of the Invention

FIG. 7 is a flowchart illustrating steps of fabricating a touch panel according to a second embodiment. In the following embodiments, the same components as those shown in FIGS. 1-4 will be indicated by the same reference characters to omit detailed description thereof.

In the first embodiment, the translucent material 31 having a suitably controlled refractive index is provided in the gap 26 between the first and second electrodes 11 and 12 formed with the conductive film (ITO transfer film). In the second embodiment, a translucent material 31 having suitably controlled light transmittance and color tone is provided in the gap 26 between the electrodes 11 and 12 formed with a transparent conductive film.

Specifically, like the touch panel of the first embodiment, the touch panel 10 of the present embodiment includes the first and second electrodes 11 and 12 shaped as shown in FIG. 1.

The first and second electrodes 11 and 12 are formed with an organic transparent conductive film (an organic conductive polymer) as a conductive film. Examples of the organic transparent conductive film include, for example, “CLEVIOUS” of H. C. Stark, “DENATRON” (registered trademark) of Nagase Chemtex Corporation, “ORMECON” (registered trademark) of Nissan Chemical Industries, Ltd., “SEPLEGYDA” (registered trademark) of Shin-Etsu Polymer Co., Ltd., etc. A thickness of the organic transparent conductive film is controlled in such a manner that the organic transparent conductive film has a surface resistance suitable for the touch point sensing electrodes 11, 12.

The above-listed organic transparent conductive films are resistant to a temperature higher than a temperature during the fabrication of the liquid crystal display panel. Thus, the organic transparent conductive film can directly be formed on the surface of the liquid crystal display panel, thereby suitably reducing the entire thickness of the display panel. The organic transparent conductive film is made of a transparent conductive material which is water-soluble before curing.

An insulating translucent material 31 is provided in the gap 26 between the first and second electrodes 11 and 12 adjacent to each other, and the translucent material 31 has the same light transmittance and color tone as the organic transparent conductive film. A thickness of the translucent material 31 is controlled to have the same color tone as the organic transparent conductive film constituting the electrodes 11, 12.

For example, when the organic transparent conductive film is blue transparent, the translucent material 31 is colored by mixing ink etc. to be blue transparent. The translucent material 31 is water-repellent. The translucent material 31 may be made of a silicon-based resin, an epoxy-based resin, etc., colored with a coloring material such as a dye etc., and a thickness of the translucent material 31 may suitably be controlled.

For example, the silicon-based resin etc. may be a thermosetting resin or an ultraviolet curable resin. Examples of the silicon-based resin include, for example, sylgard 184 (registered trademark) of Dow Corning Toray Co., Ltd. etc. The dye may be, for example, Blue N of Nippon Kayaku Co., Ltd.

Examples of the blue coloring material (ink) include, for example, TE-515 of Yoshikawa Chemical Co., Ltd. etc.

Using the coloring material (ink) is preferable because fabrication steps can be reduced. Using the silicon-based resin etc. is preferable because of the color tone can be adjusted by the dye.

### —Fabrication Method—

A method for fabricating the touch panel 10 and the liquid crystal display device 1 of the second embodiment will be described below.

The liquid crystal display device 1 of the second embodiment is fabricated in the same manner as the first embodiment. In fabricating the touch panel 10, the first and second electrodes 11 and 12, and the translucent material 31 are formed on the substrate 35.

Specifically, in a step of forming the touch panel, for example, blue insulating ink, or a silicon-based resin in which a blue dye is dissolved is applied as the insulating translucent material 31 to a region for forming the gap 26 between the first and second electrodes 11 and 12 in a first step shown as S21 in FIG. 7. The application may suitably be performed by, for example, silk screen printing, offset printing, etc. A suitable application method is selected based in view of a required thickness of the translucent material 31.

Then, as shown in a second step S22, a transparent conductive material constituting the organic transparent conductive film is applied by printing such as screen printing, dipping, spraying, or by using a roll coater, a slit coater, a spin coater, etc. The transparent conductive material has the same light transmittance and color tone as the organic transparent conductive film.

Since the transparent conductive material is water-soluble, the transparent conductive material is repelled by the water-repellent translucent material 31. Then, the transparent conductive material is cured to form the first and second electrodes 11 and 12 formed with the organic transparent conductive film.

### Advantages of Second Embodiment

According to the second embodiment, the water-repellent translucent material 31 is formed on the substrate 35, and then the water-soluble transparent conductive material is applied thereto. Thus, the transparent conductive material is repelled by the translucent material 31 in the region for forming the gap 26 between the first and second electrodes 11 and 12. This eliminates the step of forming the first and second electrodes 11 and 12 by patterning, and allows easy formation of the first and second electrodes 11 and 12 and the gap 26 in which the transparent material is provided.

The translucent material 31 having the same light transmittance and color tone as the organic transparent conductive film constituting the first and second electrodes 11 and 12 is provided in the gap 26 between the first and second electrodes 11 and 12 adjacent to each other. This can make the translucent material 31 provided in the gap 26 and the electrodes 11 and 12 surrounding the gap 26 less distinguishable. Specifically, this can suitably make the shape of the electrodes 11 and 12 less visible, thereby significantly improving quality of display on the liquid crystal display device 1.

### Third Embodiment of the Invention

FIGS. 8-10 show a third embodiment of the present invention.

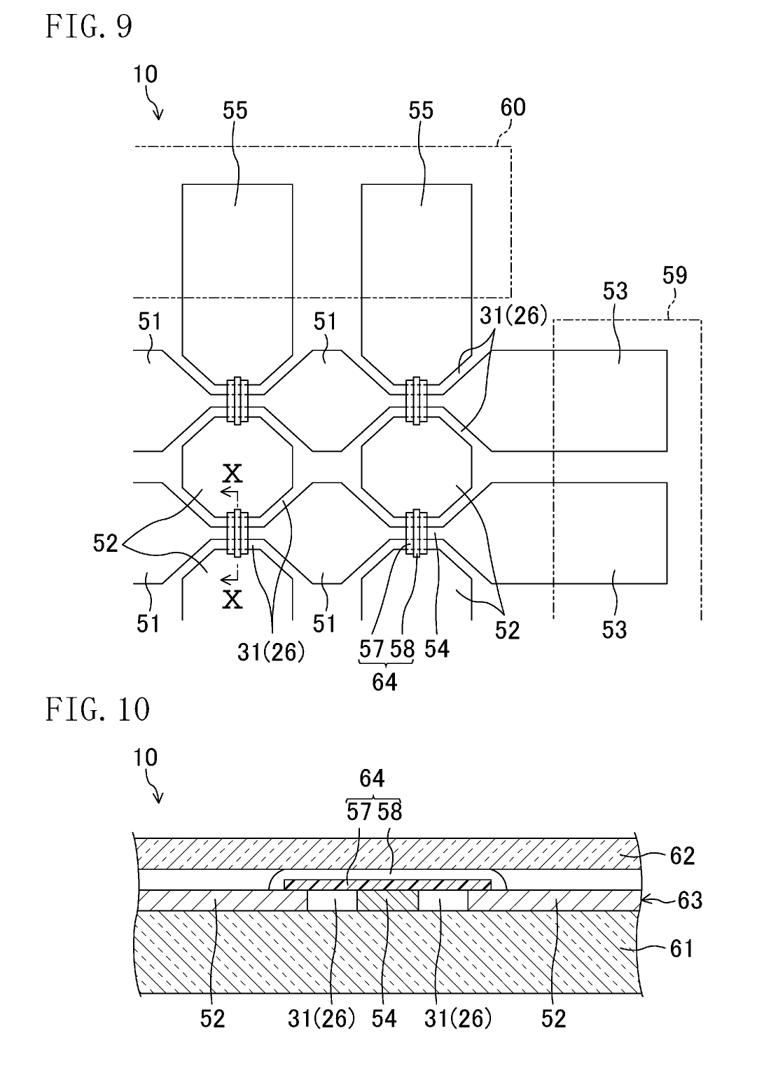

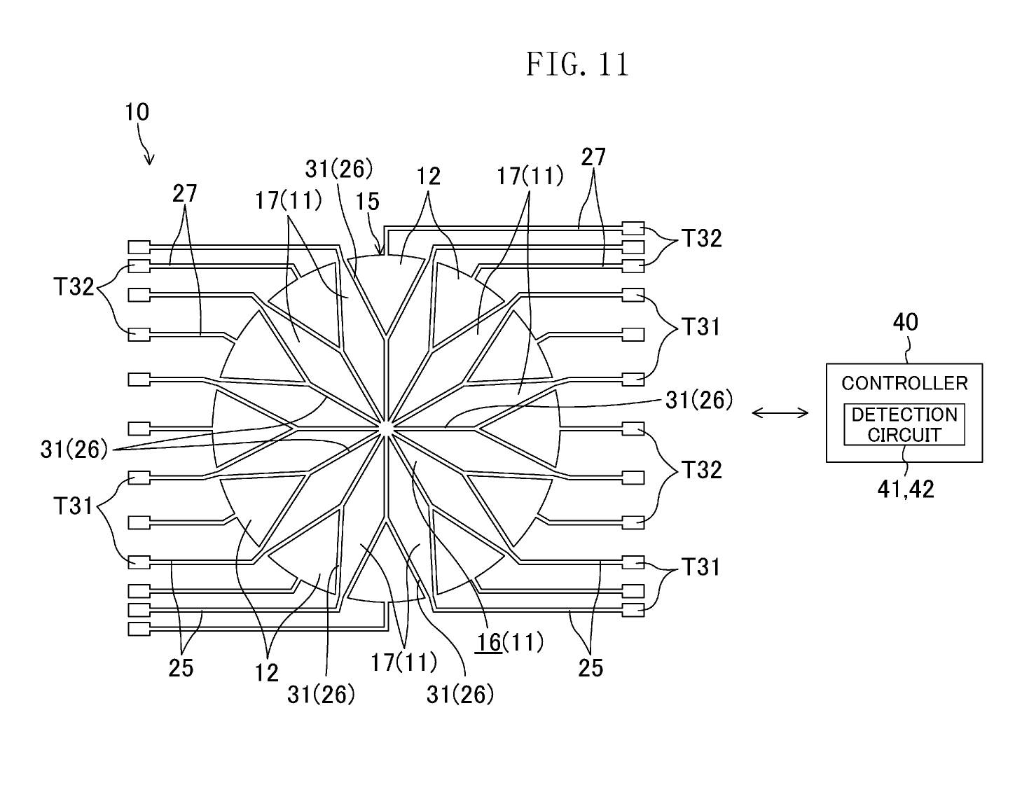

FIG. 8 is a plan view schematically illustrating a touch panel 10 of the third embodiment. FIG. 9 is a plan view illustrating a partial enlargement of FIG. 8. FIG. 10 is a cross-sectional view schematically illustrating the touch panel 10 of the third embodiment. In FIG. 8, a crosslinking structure 64 is not shown for easy understanding.

The third embodiment is different from the first embodiment in the structure of the touch location detection electrodes (first and second electrodes).

The touch panel 10 of the third embodiment is a capacitive touch panel, and is stacked on a liquid crystal display device. As shown in FIG. 10, the touch panel 10 includes a first substrate 61, a second substrate 62, a sensor layer 63 provided between the first and second substrates 61 and 62, and a crosslinking structure 64.

Each of the first substrate 61 and the second substrate 62 is a thin insulating plate having high light transmittance, and is made of, e.g., glass, polycarbonate (PC), polyethylene terephthalate (PET), a polymethylmethacrylate resin (PMMA), cyclic olefin copolymer, etc.

The sensor layer 63 includes first electrodes 51 and second electrodes 52 formed on the first substrate 61. Each of the first and second electrodes 51 and 52 has a width of about 0.05-5 mm. The first and second electrodes 51 and 52 are formed with, for example, a conductive film (an ITO transfer film), such as FLECLEAR (a registered trademark of TDK Corporation), like those of the first embodiment. Specifically, each of the first and second electrodes 51 and 52 includes a transparent conductive layer 21, and an adhesive layer 22 stacked on the transparent conductive layer 21 as shown in FIG. 3.

The first electrodes 51 are aligned at regular intervals in a lateral direction (an X-axis direction) in FIGS. 8 and 9. The first electrodes 51 adjacent to each other in the X-axis direction are integrally coupled by a coupling 54. Specifically, the first electrodes 51 and the couplings 54 are alternately arranged in the X-axis direction, and rows of the first electrodes 51 and the couplings 54 are arranged at regular intervals in a vertical direction (a Y-axis direction) in FIGS. 8 and 9. A first contact 53 is integrated with the coupling 54 at a right end of each of the rows.

The second electrodes 52 are aligned at regular intervals in the vertical direction (the Y-axis direction) in FIGS. 8 and 9. The second electrodes 52 adjacent to each other in the Y-axis direction are connected by a crosslinking structure 64. Columns of the second electrodes 52 connected by the crosslinking structures 64 are arranged at regular intervals in the X-axis direction. A second contact 55 is connected to the second electrode 52 at an upper end of each the columns through the crosslinking structure 64.

The first contacts 53 and the second contacts 55 are connected to conductive paths 59, 60 formed along sides of the first substrate 61 and the second substrate 62, respectively. The conductive paths 59, 60 are made of, for example, silver etc. Thus, the first electrodes 51 and the second electrodes 52 are connected to a controller (not shown) through the conductive paths 59, 60, respectively.

The crosslinking structure 64 includes a coating 57 and a conductive part 58 as shown in FIGS. 9 and 10. The coating 57 is formed with a thin insulating film having a dielectric constant of about 2-4, and high light transmittance. For example, the coating 57 can be formed with ink, or a thin polyethylene terephthalate (PET) film having high light transmittance.

The coating 57 is formed to cover at least the coupling 54 provided between the second electrodes 52 adjacent to each other in the Y-axis direction.

The conductive part 58 is formed with, for example, an organic transparent conductive film such as ITO, or polyethylenedioxythiophene. The conductive part 58 is formed on an upper surface of the coating 57 (i.e., a surface of the coating opposite the coupling 54), and is electrically connected to the second electrodes 52 through ends thereof extending outward from the coating 57.

A predetermined gap 26 is formed between the first and second electrodes 51 and 52 adjacent to each other, and a translucent material 31 is provided in the gap 26 in the same manner as the first embodiment. A refractive index of the translucent material 31 is equal to a refractive index of the adhesive layer 22 or a refractive index of the transparent conductive layer 21 constituting the first and second electrodes 51 and 52, or is a median between the refractive indices of the adhesive layer 22 and the transparent conductive layer 21.

When a user touches a surface of the second substrate 62, the controller (not shown) of the touch panel 10 detects a capacitance formed by the first and second electrodes 51 and 52, thereby detecting the location of the touch, and the movement of the location of the touch in the same manner as the first embodiment.

In fabricating the touch panel 10, the conductive film (the ITO transfer film) is transferred to the first substrate 61 with the adhesive layer 22 facing the first substrate 61.

Then, ultraviolet light is applied to the adhesive layer 22 of the conductive film to cure the adhesive layer 22. In the same manner as the first embodiment, the conductive film adhered to the first substrate 61 is processed by a laser to form the plurality of first electrodes 51 and second electrodes 52. The laser application forms the gap 26 between the first and second electrodes 51 and 52 adjacent to each other.

The insulating translucent material 31 is then provided in the gap 26 between the first and second electrodes 51 and 52 adjacent to each other. The translucent material 31 is, for example, an ultraviolet curable resin, or a thermosetting resin. The translucent material 31 applied to fill the gap 26 is cured by applying ultraviolet light, or by heating.

As described above, the refractive index of the cured translucent material 31 is equal to the refractive index of the adhesive layer 22 or the refractive index of the transparent conductive layer 21 constituting the first and second electrodes 512 and 52, or is a median between the refractive indices of the adhesive layer 22 and the transparent conductive layer 21. Thus, the touch panel 10 is fabricated.

### Advantages of Third Embodiment

According to the third embodiment, the first and second electrodes 51 and 52 are formed with the conductive film (the ITO transfer film). Thus, the first and second electrodes 51 and 52 can easily be formed by laser processing in the same manner as the first embodiment.

The refractive index of the translucent material 31 provided in the gap 26 is set equal to the refractive index of the adhesive layer 22 or the refractive index of the transparent conductive layer 21 constituting the conductive film, or is set to a median between the refractive indices of the adhesive layer 22 and the transparent conductive layer 21. This can reduce a difference between the refractive index of the gap 26 and the refractive index of the electrodes 11, 12 surrounding the gap. Thus, in the same manner as the first embodiment, the pattern of the electrodes 51 and 52 can be less visible to the users, thereby improving quality of display on the liquid crystal display device 1.

### Fourth Embodiment of the Invention

In the third embodiment, the translucent material 31 having a suitably controlled refractive index is provided in the gap 26 between the first and second electrodes 51 and 52 formed with the conductive film (the ITO transfer film). In the fourth embodiment, like the second embodiment, a translucent material 31 having suitably controlled light transmittance and color tone is provided in the gap 26 between the electrodes 51, 52 formed with a transparent conductive film.

Specifically, the touch panel 10 of the present embodiment includes first electrodes 51 and second electrodes 52 shaped as shown in FIGS. 8-10 like the touch panel of the third embodiment. The first and second electrodes 51 and 52 are formed with an organic transparent conductive film (an organic conductive polymer) as a conductive film like those of the second embodiment.

An insulating translucent material 31 is provided in a gap 26 between the first and second electrodes 51 and 52 adjacent to each other, and the translucent material 31 has the same light transmittance and color tone as the organic transparent conductive film. A thickness of the translucent material 31 is controlled to have the same color tone as the organic transparent conductive film constituting the electrodes 51, 52.

### Advantages of Fourth Embodiment

According to the fourth embodiment, like the second embodiment, the translucent material 31 provided in the gap 26 and the electrodes 51 and 52 surrounding the gap are less distinguishable. This can suitably make the shape of the electrodes 51, 52 less visible, thereby significantly improving quality of display on the liquid crystal display device 1.

### Fifth Embodiment of the Invention

FIG. 11 shows a fifth embodiment of the present invention.

FIG. 11 is a plan view schematically illustrating a touch panel 10 of the fifth embodiment.

The fifth embodiment is different from the first embodiment in the structure of the touch location detection electrodes (the first and second electrodes). Specifically, the touch panel 10 of the fifth embodiment is formed on an outer surface of a counter substrate 37 of a flat liquid crystal display device 1.

As shown in FIG. 11, the touch panel 10 includes a touch region 15, a plurality of touch location detection electrodes 11, 12 arranged in the touch region 15, and a controller 40 as a circuit for detecting the location of the touch based on a change in capacitance formed between the touch location detection electrodes 11, 12 and an object.

The touch location detection electrodes 11, 12 include first electrodes 11 and second electrodes 12 formed with, for example, a conductive film (an ITO transfer film) such as FLECLEAR (a registered trademark of TDK Corporation).

The plurality of first electrodes 11, each of which is in the shape of a narrow rhomboid, are provided in the touch region 15 as shown in FIG. 11. Ends of the first electrodes 11 are converged to the center of the touch region 15, while the other ends extend radially outward from the center of the touch region 15.

Thus, each of the first electrodes 11 includes a center portion 16 arranged at the center of the touch region 15, and a tip end 17 extending radially outward from the center portion 16 to reach a periphery of the touch region 15. A terminal T31 is provided at an end of a wire 25 drawn from the tip end 17 of each of the first electrodes 11. The wires 25 are drawn to the right or left as shown in FIG. 11.

As shown in FIG. 11, the second electrodes 12 are arranged along the periphery of the touch region 15 between the tip ends 17 adjacent to each other. Each of the second electrodes 12 is in the shape of a wedge. A predetermined gap 26 is provided between the first and second electrodes 11 and 12 adjacent to each other. The gaps 26 have substantially the same width.

Wires 27 are drawn from the second electrodes 12, respectively, and terminals T32 are provided at ends of the wires 27. As shown in FIG. 11, each of the wires 27 is drawn to the right or left, and is arranged in the gap 26. The terminals T31, T32 are connected to the controller 40. The controller 40 is configured in the same manner as that of the first embodiment.

The gap 26 is formed by applying a laser to the conductive film adhered to the counter substrate 37 with the adhesive layer 22 facing the counter substrate. Specifically, the first and second electrodes 11 and 12 are formed by applying the laser to the conductive film adhered to the counter substrate 37.

A translucent material 31 is provided in the gap 26 between the touch location detection electrodes 11, 12 adjacent to each other in the same manner as the first embodiment. A refractive index of the translucent material 31 is equal to a refractive index of the adhesive layer 22 or a refractive index of the transparent conductive layer 21 constituting the first and second electrodes 11, 12, or is a median between the refractive indices of the adhesive layer 22 and the transparent conductive layer 21.

The controller 40 has the same structure as that of the first embodiment, and is configured to compare signals from the terminals T31 at the tip ends 17 detected by a capacitance detection circuit 41 or an impedance detection circuit 42 to detect a location of a touch at the center portion 16, or scrolling operation in a direction of an outer circumference of the touch region 15.

The controller 40 further compares a signal detected from the tip end 17, and a signal detected from the second electrode 12 to detect a location of a touch from the center of the touch region 15 in a radial direction, or scrolling operation in the direction of the outer circumference of the touch region 15.

### Advantages of Fifth Embodiment

According to the fifth embodiment, the first and second electrodes 11 and 12 are formed with the conductive film (the ITO transfer film). Thus, the electrodes 11, 12 can easily be formed by laser processing in the same manner as the first embodiment.

Further, the refractive index of the translucent material 31 provided in the gap is set equal to the refractive index of the adhesive layer 22 or the refractive index of the transparent conductive layer 21 constituting the conductive film, or is set to a median between the refractive indices of the adhesive layer 22 and the transparent conductive layer 21. This can make the pattern of the electrodes 11, 12 less visible to the users, thereby improving quality of display on the liquid crystal display device 1 in the same manner as the first embodiment.

### Sixth Embodiment of the Invention

In the fifth embodiment, the translucent material 31 having the suitably controlled refractive index is provided in the gap 26 between the first and second electrodes 11 and 12 formed with the conductive film (the ITO transfer film). In a sixth embodiment, like the second embodiment, a translucent material 31 having suitably controlled light transmittance and color tone is provided in the gap 26 between the electrodes 11, 12 formed with a transparent conductive film.

Specifically, like the touch panel of the fifth embodiment, a touch panel 10 of the present embodiment includes first electrodes 11 and second electrodes 12 shaped as shown in FIG. 11. The electrodes 11, 12 are formed with an organic transparent conductive film (an organic conductive polymer) as a conductive film in the same manner as the second embodiment.

An insulating translucent material 31 is provided in the gap 26 between the first and second electrodes 11 and 12 adjacent to each other, and the translucent material 31 has the same light transmittance and color tone as the organic transparent conductive film. A thickness of the translucent material 31 is controlled to have the same color tone as the organic transparent conductive film constituting the electrodes 11, 12.

### Advantages of Sixth Embodiment

According to the sixth embodiment, the translucent material 31 provided in the gap 26 and the electrodes 11, 12 surrounding the gap 26 are less distinguishable like those of the second embodiment. This can suitably make the shape of the electrodes 11, 12 less visible, thereby significantly improving quality of display on the liquid crystal display device 1.

### Other Embodiments

In the above embodiments, the flat touch panels have been described. However, the present invention is not limited thereto, and can be applied to touch panels having a dome-shaped surface, for example. This can improve convenience of the users. For example, the touch location detection electrodes 11, 12 according to the fifth embodiment can be formed on a convex-shaped surface.

In the first, third, and fifth embodiments, the ITO transfer film has been used as the conductive film. However, the present invention is not limited thereto. The conductive film may be formed with a film including a transparent conductive layer 21 containing a large number of other conductive particles.

In the second, fourth, and sixth embodiments, the translucent material 31 having the same light transmittance and color tone as the electrodes 11 (51), 12 (52) is provided in the gap 26 between the electrodes 11 (51), 12 (52) adjacent to each other. However, a pattern made of color filters having the same light transmittance and color tone as the electrodes 11 (51), 12 (52) may be formed on the substrate constituting the display panel 2. In this case, the color filter pattern is preferably formed on a layer different from a color filter used for the display. The color filter pattern may be formed on a cover glass provided above or below the electrodes 11 (51), 12 (52).

A region of the display device corresponding to the gap 26 between the electrodes 11 (51), 12 (52) may be displayed in the same color tone as the electrodes 11 (51), 12 (52). Specifically, the shape of the gap 26 obtained by image recognition is reflected on data displayed on the display panel 2. Thus, the same color as the electrodes 11, 12 is constantly displayed in the gap 26, thereby making the shape of the electrodes 11 (51), 12 (52) less visible.

In the above-described embodiments, the liquid crystal display panel 2 has been described as an example of the display element. However, the present invention is not limited thereto, and can be applied to, for example, display devices including other display elements, such as organic EL display panels etc.

As described above, the present invention is useful for capacitive touch panels, a method for fabricating the capacitive touch panels, display devices, and a method for fabricating the display devices.

1. A touch panel, comprising:
a touch region for detecting a location of a touch by an object; and
a plurality of touch location detection electrodes arranged in the touch region, the touch panel being configured to detect the location of the touch based on a capacitance formed between the touch location detection electrodes and the object, wherein
an optical characteristic of the touch region in a gap between the touch location detection electrodes adjacent to each other is substantially equal to an optical characteristic of the touch location detection electrodes.

2. The touch panel of claim 1, wherein
each of the touch location detection electrodes is formed with a conductive film including a transparent conductive layer, and an adhesive layer stacked on the transparent conductive layer,
an insulating translucent material is provided in the gap between the touch location detection electrodes adjacent to each other, and
a refractive index of the translucent material is equal to a refractive index of the adhesive layer or a refractive index of the transparent conductive layer, or is a median between the refractive index of the adhesive layer and the refractive index of the transparent conductive layer.

3. The touch panel of claim 1, wherein
the gap is formed by applying a laser to the conductive film.

4. The touch panel of claim 1, wherein
the transparent conductive layer is formed with a layer containing multiple transparent conductive particles.

5. A touch panel, comprising:
a touch region for detecting a location of a touch by an object; and
a plurality of touch location detection electrodes arranged in the touch region, the touch panel being configured to detect the location of the touch based on a capacitance formed between the touch location detection electrodes and the object, wherein
the touch location detection electrodes are formed with a transparent conductive film,
an insulating translucent material is provided in a gap between the touch location detection electrodes adjacent to each other, and
light transmittance and color tone of the translucent material are the same as light transmittance and color tone of the transparent conductive film.

6. The touch panel of claim 5, wherein
the transparent conductive film is made of a transparent conductive material which is water-soluble before curing, and
the translucent material is a water-repellent coloring material.

7. A display device, comprising:
the touch panel of claim 1 formed directly on a surface of a substrate constituting a display element.

8. A method for fabricating the display device of claim 7, the method comprising:
bonding a first substrate on which a liquid crystal material is fed by dropping to a second substrate to form a large base substrate as an assembly of multiple ones of the display element;
forming the touch panel directly on a surface of the first or second substrate of the base substrate; and
dividing the base substrate on which the touch panel is formed by the display elements to fabricate a plurality of liquid crystal display devices.

9. A method for fabricating a touch panel which includes a touch region for detecting a location of a touch by an object, and a plurality of touch location detection electrodes arranged in the touch region, and is configured to detect the location of the touch based on a capacitance formed between the touch location detection electrodes and the object, the method comprising:
bonding a conductive film including a transparent conductive layer and an adhesive layer stacked on the transparent conductive layer to a substrate with the adhesive layer facing the substrate;
forming the plurality of touch location detection electrodes by applying a laser to the conductive film bonded to the substrate; and
providing an insulating translucent material in a gap between the touch location detection electrodes adjacent to each other, wherein
a refractive index of the translucent material is equal to a refractive index of the adhesive layer or a refractive index of the transparent conductive layer, or is a median between the refractive index of the adhesive layer and the refractive index of the transparent conductive layer.

10. The method of claim 9, wherein
the transparent conductive layer is formed with a layer containing multiple transparent conductive particles.

11. A method for fabricating a touch panel which includes a touch region for detecting a location of a touch by an object, and a plurality of touch location detection electrodes arranged in the touch region, and is configured to detect the location of the touch based on a capacitance formed between the touch location detection electrodes and the object, the method comprising:
forming on a substrate the plurality of touch location detection electrodes formed with a transparent conductive film, and an insulating translucent material provided in a gap between the touch location detection electrodes adjacent to each other, wherein
light transmittance and color tone of the translucent material are the same as light transmittance and color tone of the transparent conductive film.

12. The method of claim 11, wherein
the transparent material made of a water-repellent coloring material is formed on the substrate, and then a water-soluble transparent conductive material is applied and cured to form the transparent conductive film.

13. The method of claim 9, wherein
the substrate on which the plurality of the touch location detection electrodes and the translucent material are formed is divided to fabricate multiple ones of the touch panel.

14. The touch panel of claim 2, wherein the gap is formed by applying a laser to the conductive film.

15. The touch panel of claim 2, wherein the transparent conductive layer is formed with a layer containing multiple transparent conductive particles.

16. The touch panel of claim 3, wherein the transparent conductive layer is formed with a layer containing multiple transparent conductive particles.

17. The method of claim 10, wherein the substrate on which the plurality of the touch location detection electrodes and the translucent material are formed is divided to fabricate multiple ones of the touch panel.

18. The method of claim 11, wherein the substrate on which the plurality of the touch location detection electrodes and the translucent material are formed is divided to fabricate multiple ones of the touch panel.

19. The method of claim 12, wherein the substrate on which the plurality of the touch location detection electrodes and the translucent material are formed is divided to fabricate multiple ones of the touch panel.
